(19) United States
(12) Patent Application Publication
(10) Pub. No.: US 2011/0186948 A1
(43) Pub. Date: Aug. 4, 2011

(54) Semiconductor-Based Magnetic Material

(76) Inventors: Pascal Pochet, La Murette (FR); Emmanuel Arras, Grenoble (FR)

(21) Appl. No.: 13/055,475

(22) PCT Filed: Jul. 21, 2009
(86) PCT No.: PCT/FR2009/000895

§ 371 Date: Apr. 5, 2011

(30) Foreign Application Priority Data
Jul. 22, 2008 (FR) 08 04159

(51) Int. Cl. H01L 29/82; H01F 1/40; B32B 15/04; B32B 15/01; C30B 23/02; H01F 1/04

(52) U.S. Cl. 257/421; 428/611; 428/469; 428/472.3; 428/450; 117/108; 252/62.55; 257/E29.323

(57) ABSTRACT

Magnetic material based on at least one magnetic 3d transition metal element and at least one Group IVA semiconductor element, this material being homogeneous and having a Curie temperature (Tc) of 350 K or higher. Method for the production and uses thereof, especially in spintronics.

The invention relates to a novel magnetic material based on at least one magnetic 3d transition metal element and at least one semiconductor element of group (IVA), selected from among germanium, silicon and their alloys, this material being homogeneous and crystalline, and having a Curie temperature (Tc) equal to or greater than 350 K. It also relates to a method for its production and to its uses, particularly in spintronics. The diamond structure of this material also gives it numerous possibilities for the co-integration of magnetic functions (magnetic sensors, magnetic memories, etc.) in conventional microelectronics.

According to a preferred embodiment, the invention relates to the synthesis of a homogeneous magnetic material, based on germanium and manganese, which is magnetic above room temperature.

The injection of a spin-polarized current of carriers into a semiconductor, which is characterized by an excess of one of the two carrier populations present (for example that of parallel spin or “spin up”), has recently been the subject of several publications. By way of example, mention may be made of the electronic components described in the article Datta and Das, Applied Physics Letters, 56, 665, 1990 and in Vutic et al., Reviews of Modern Physics, Volume 76, 323, April 2004.

The use of this injection of a spin-polarized current is of great interest in microelectronics, but its development suffers from the lack of suitable materials for forming the current injection electrode.

This is because although conventional ferromagnetic metals such as iron and many of its alloys have some of the requisite properties such as high spin polarization and ferromagnetic behavior at room temperature, their electrical resistance is several orders of magnitude different to that of semiconductors, which leads to great implementation difficulties and makes it necessary to carry out the current injection by the tunnel effect (cf: A. Fert and H. Jaffres, Physical Review B 64, 184420). This has the drawback of requiring the growth of a hybrid heterostructure which is difficult to produce, of the semiconductor/tunnel effect barrier/ferromagnetic metal type.

On the other hand, there are so-called diluted magnetic semiconductors (abbreviated to DMS) which do not present the drawback of having a resistivity very different to that of ordinary semiconductors. These DMS typically consist of a semiconductor matrix of groups III-V, IV or II-VI, in which magnetic impurities such as manganese, iron, chromium, cobalt, vanadium or nickel are diluted.

In the case of dilution with manganese, which is an acceptor in III-V or IV semiconductors, the charge carriers consist of holes. When the concentration of manganese and the density of holes (naturally created by the presence of manganese or intentionally introduced by co-doping) are sufficiently high in the DMS, it can become ferromagnetic and the exchange coupling between manganese ions is induced by the holes. The first ferromagnetic DMS to be synthesized was InMnAs in 1992 (H. Ohno et al., Phys. Rev. Lett. 68, 2664 (1992)). Since then, numerous other ferromagnetic DMS have been manufactured, such as GaMnAs (H. Ohno et al., Science 281, 951 (1998)), ZnMnTe (D. Ferrand et al., Phys. Rev. B 63, 085201 (2001)), ZnCrTe (H. Saito et al., Phys. Rev. Lett. 90, 207202 (2003)) or GaMnN (M. L. Reed et al., Appl. Phys. Lett. 79, 3473 (2001)).

A major drawback of these DMS is that they all still have a Curie temperature Tc (temperature up to which the semiconductor has ferromagnetic properties) less than or equal to room temperature (typically ≦300 K approximately). For example, reference may be made to the article K. W. Edmonds et al., Phys. Rev. Lett. 92, 037201, 2004, which describes a semiconductor of formula GaMnAs having a Curie temperature of only about 159 K, and to the article H. Saito et al., Phys. Rev. Lett. 90, 207202, 2003, which describes DMS corresponding to the formula Zn₁₋ₓCrₓTe and having a Curie temperature substantially equal to 300 K (±10 K), when x=0.20.

Another drawback of these DMS resides in the undesirable but frequent formation of small ferromagnetic metallic precipitates within the semiconductor matrix, which is not favorable for genuinely ferromagnetic properties for these DMS and makes the step of growing the crystals very difficult to carry out.

It will furthermore be noted that the use of these materials based on gallium or tellurium is very difficult to envisage on substrates made of silicon, the basic material of the microelectronics industry.

Patent Application U.S. Pat. No. 6,946,301 discloses a method of manufacturing out of equilibrium by thermal evaporation an amorphous ferromagnetic semiconductor of the GeMn type which has a Curie temperature that can reach 250 K, with a manganese fraction of about 35%.

In its only exemplary embodiment, Patent Application U.S. Pat. No. 6,307,241 teaches the manufacture of a type III-V ferromagnetic semiconductor (GaAs) with a Curie temperature Tc higher than 400 K, by the technique of ion implantation of manganese ions (Mn⁺) followed by an anneal. As is known to the person skilled in the art (see in particular the article Magnetooptical Study of Mn ions Implanted in Ge, Franco D'Orazio et al., IEEE Transactions on Magnetics, Vol. 38, No. 5, September 2002), it will be noted that this implantation technique is not suitable for the manufacture of magnetic materials based on a group IVA semiconductor element (typically based on germanium) with Tc≧350 K given that the phase thus obtained, of the Ge₃Mn₅ type, has a Tc never exceeding 300 K.

A major drawback of these known magnetic semiconductors resides in their relatively low Curie temperature, which is generally limited to about 300 K. Furthermore, when the measured Curie temperature is close to 300 K, it is difficult to exclude the presence of the metallic Ge₃Mn₅ phase, whose Curie temperature is specifically close to 300 K.

A solution recently proposed by Jamet et al. (Jamet et al. Nature Materials 5, 653-659, 2006; WO2007/090946) consists in synthesizing an alloy of germanium and manganese constituting a magnetic semiconductor having a Curie temperature higher than room temperature. This material is characterized by a spatial modulation of the manganese composition, which modulation allows the appearance of the magnetic semiconductor phase in the manganese-rich regions. These manganese-enriched regions do not have a composition similar to that of the known compounds of the phase diagram of the Ge—Mn binary alloy. They can then be used for a variety of applications in spintronics. This spatial inhomogeneity, however, which gives rise to the good properties of this material, also limits its use in devices which would require more of a homogeneous phase, for example an electrode for injecting a spin-polarized current which is of great interest in microelectronics, or such as the FET spin transistor, the spin Qbit or information storage devices of the MRAM type.

V. Ko et al., AIP Conf. Proc. 893, 1229 (2007) have described a ferromagnetic compound with a Tc above 400° C. of the DMS type and of the formula Si_{0.75}Ge_{0.25} with an average Mn concentration of 8 and 12%, obtained after implanting Mn % ions followed by annealing at 800 or 900° C. After analysis of samples by EXAFS and TEM (transmission electron microscopy), this material is found to be inhomogeneous and composed of small ferromagnetic metallic precipitates within the semiconductor matrix (“Correlation of structural and magnetic properties of ferromagnetic Mn-implanted Si₁₋ₓGeₓ films” V. Ko, et al., J. Appl. Phys. 103, 053912 (2008)). The same type of material has been produced by implanting Mn % in Si₁₋ₓGeₓ with x varying from 0 to 0.5: the material obtained was likewise not homogeneous, with metallic precipitates of the Mn₄Si₇ type for x<0.2 and of the Mn₇Ge₃ type for x>0.2 (V. Ko, et al., J. Appl. Phys. 103, 053912 (2008)). The presence of these small metallic precipitates within the semiconductor matrix does not allow genuinely ferromagnetic properties to be obtained for these materials.

U.S. Pat. No. 5,296,048 describes a semiconductor material born into the family of groups III-V or materials of group IV, with which a transition element or a rare earth is associated in a quantity sufficient to impart magnetic properties to the material. The materials described in this document are diluted semiconductors (DMS); when a material of group IV is employed, the magnetic element is present with a maximum concentration of less than 1%.

The document M. Bolduc et al., Physical Review B71, 033302 (2005) describes an Mn/Si material with a Curie temperature higher than 400 K. The materials described in this document are diluted semiconductors (DMS); the magnetic element is present with a maximum concentration of less than 0.8%.

The document S. Demidov et al., JETP Letters, vol. 83, 25/08/06, 568-571 describes magnetic semiconductor materials based on Ge or Si and Mn or Fe. In these materials, the magnetic element is present with a concentration of between 13 and 15%. These materials are obtained by a method (laser ablation) different to that of the invention. The resistivity values measured by the authors (between 10⁻⁴ and 10⁻⁶ ohm.m) also mean that the presence of metallic precipitates may be assumed.

The present invention proposes to prepare a novel homogeneous crystalline magnetic material, in particular a dilute solid solution of Mn in Ge, which is not described in the equilibrium phase diagram (at atmospheric P, the Temperature/Concentration diagram) of this material. This is because in the case of GeMn, the limit of solubility of Mn in Ge is very much less than 0.1 at %. Beyond this limit, precipitation of an Mn-rich phase (Mn₁₁Ge₈ or Mn₅Ge₃) in a Ge matrix should be obtained. The material of the invention exists in a concentration range around 20-45 at % Mn. This concentration is less than that of the Mn-rich precipitates mentioned above (respectively 58 and 62.5 at %). In the prior art, the embodiments relate to crystalline materials whose Mn concentration is less than 15 at %. Furthermore, high-performance analyses of such materials (TEM) have revealed the precipitation of a second Mn₁₁Ge₈ or Mn₅Ge₃ phase, and these materials are therefore not homogeneous.

In contrast to amorphous materials, crystalline materials have long-range order in their structure. Crystalline materials can be distinguished from amorphous materials by X-ray diffraction experiments, for example on a solid material or on a powder: a crystal gives rise to spatially localized diffraction peaks while an amorphous compound produces wide maxima. The first maximum corresponds to the correlations between a given atom and its nearest neighbors, the second corresponds to the correlations between this atom and its second nearest neighbors, etc. The width of the maxima increases with the order of the neighbors, which means that the correlations become weaker and weaker: the local order for a given atom does not extend beyond the 5^{th} or 6^{th} neighbors.

Besides the advantages mentioned above, in so far as it is crystalline, the material allows repeated epitaxy for the crystalline layers which are subsequently deposited on its surfaces in order to prepare electronic devices or complete spintronics; such repetition would be much more difficult to carry out if the material were amorphous. Furthermore, the crystalline structure of the material makes it possible to ensure a large spin diffusion length, a crucial parameter in spintronics, which is greater in comparison with that expected in amorphous materials.

It is an object of the present invention to provide a substantially homogeneous crystalline magnetic material which makes it possible to overcome the aforementioned drawbacks both of metals (the material of the invention has a resistivity of about 10⁻³ ohm.m, as opposed to less than 10⁻⁷ ohm.m for metals) and known DMS (the material of the invention has a Curie temperature greater than or equal to 350 K), and this object is achieved with the aid of a magnetic material based on at least one element of group IVA, preferably Ge and/or Si, comprising at least one transition element selected from the group consisting of manganese, iron, cobalt, nickel, vanadium and chromium, the properties of the material being obtained owing to the stabilization of the transition element, in particular manganese, at an interstitial position of the diamond lattice. This position of the transition element, in particular manganese, in the semiconductor structure is induced by keeping the material in deformation during its fabrication.

It is another object to provide a magnetic material whose Tc is controllable, with the Tc capable of exceeding room temperature. Furthermore, according to a variant of the invention, it is possible to prepare a material having zones localized according to a predetermined scheme in which the magnetism and the Tc are controlled and different to those of the other parts of the material. The possibility of obtaining magnetic zones whose Tc can be different on the same device may also be used to make it possible to produce a device whose response is a function of temperature, for example a flat magnetic memory.

To this end, a novel synthesis method has been developed, this synthesis route making it possible to obtain a film of a homogeneous material, an alloy of a semiconductor, advantageously germanium, and a transition element, advantageously manganese, this film being magnetic at room temperature and having properties comparable to those of the manganese-enriched phase of the alloys fabricated by using the method described in WO2007/090946. This synthesis route makes it possible to obtain a germanium and manganese alloy which is magnetic, in the form of a film with a homogeneous composition. The synthesized material, to which the invention relates, is characterized by a high Curie temperature. When it is composed of Ge and Mn, its composition and its structure are different to those of the known compounds of the phase diagram of the Ge—Mn binary alloy (Ge₃Mn₅ or GeMn₁₁).

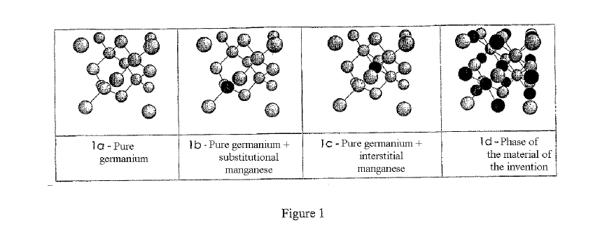

In particular, the transition element is for the most part in an interstitial position in the crystalline structure of the semiconductor (lattice of the diamond type). A certain proportion of the transition element in a substitutional position is nevertheless necessary in order to obtain a magnetic material with non-zero magnetization in the neutral state. Furthermore, the Curie temperature of this material is controlled by the proportion of the transition element in a substitutional position (with respect to the interstitial position) (see FIG. 1).

In a basic alloy: on the one hand a crystalline material A, and on the other hand an element B, the element B may occupy at least 2 different types of position in the structure of A (see FIG. 1a-1c). In the case presented, the crystalline material A is germanium (FIG. 1a) and the element B is manganese. The element B may be located:

In a substitutional position (FIG. 1b), each atom of B taking the place of an atom of A. This is a conventional form of an alloy referred to as substitution. However, a conventional alloy of a transition element such as Mn in a semiconductor such as Ge does not make it possible to obtain Curie temperatures higher than room temperature.

In an interstitial position (FIG. 1c) the lattice of the atoms A being maintained and each atom of B being located in the interstices of the crystal A (for example of the octahedral or tetrahedral sites in the case of the diamond lattice). This is a form of alloy referred to as insertion. This type of alloy is normally observed with elements B of small size, for example hydrogen, boron, carbon or nitrogen.

Advantageously, in the material of the invention, between 15 and 45% of the transition element is in a substitutional position (with respect to the total quantity of transition element), and preferably between 20 and 35%.

The magnetic material of the invention can be obtained by virtue of a novel method which has a plurality of variants and the characteristics of which are as follows:

The method of manufacturing a magnetic material according to the invention includes at least one molecular beam epitaxy step comprising simultaneous deposition of at least one transition element selected from the group consisting of manganese, iron, cobalt, nickel, vanadium and chromium and at least one other element selected from group IVA of the periodic table onto a substrate are selected according to criteria which are defined below.

The temperature of the substrate during the deposition is subject to adjustment. Nevertheless, this growth temperature is very much less than the growth temperatures of between 550° C. and 600° C. which are commonly used in the epitaxy of group IV semiconductor materials. The reason is that this procedure makes it possible to stabilize metastable phases rich in magnetic elements such as manganese.

The choice of the substrate constitutes an essential characteristic of the method of the invention. The substrate advantageously consists of a binary or ternary or optionally quaternary semiconductor alloy of diamond or zinc blende structure (optionally of the Wurtzite type). The atoms involved in the composition of the substrate may in particular be selected from among the following elements:

Al, In, Ga, As, Sb, P, C, Si, Ge.

Preferably, the substrate used for carrying out this method is based on one or more atoms selected from the group consisting of (In, Ga, As, Sb, P) or (Si, Ge, C) and the alloys thereof, for example:

In₁₋ₓGaₓAs, GaAs₁₋ₓSbₓ

where x represents a number such that

1≦x≦1 or

Si_{1-x-y}GeₓC_{y}

where x and y represent numbers such that

0≦x, 0≦y, 0≦x+y≦1.

According to a first variant, the method of manufacturing a magnetic material according to the invention includes at least one molecular beam epitaxy step comprising simultaneous deposition of at least one transition element selected from the group consisting of manganese, iron, cobalt, nickel, vanadium and chromium and at least one other element selected from group IVA of the periodic table onto a substrate whose lattice mismatch with the element(s) selected from group IVA of the periodic table is between 0.1 and 10% in absolute value, and whose temperature during the growth of the crystals is between 80° C. and 200° C., preferably between 100° C. and 150° C., leading to a thin film of said group IVA semiconductor being obtained, in which the atoms of magnetic element(s) are inserted.

The support is selected so that its lattice parameter is greater or less by from 0.1 to 10% than that of the semiconductor (element selected from group IVA) used for the material of the invention, advantageously between 1 and 5%, and preferably between 2 and 4% when the group IVA element is germanium and the transition element is manganese.

The expansion or contraction of the substrate may be modulated in order to control the relative stability of the interstitial defects with respect to the substitutionals in the following way: in germanium at equilibrium, without strain, it is the substitutional position which is stable. In order to obtain the magnetic structure in germanium, which is a constituent of the material according to the invention, it is necessary to promote the formation of interstitials with respect to substitutionals. Stabilization of such a structure is obtained in Ge by virtue of an expansion strain which stabilizes the interstitial with respect to the substitutional (lattice parameter of the substrate greater by from 0.1 to 10% than that of Ge). This strain is obtained owing to the use of a substrate having a lattice parameter greater than that of Ge; particularly, an expansion of from 2 to 4%, and in particular 3%, gives good results.

In silicon, the situation is reversed: it is the interstitial which is stable at equilibrium while the substitutional is less stable, and it is therefore necessary to use a substrate making it possible to contract the silicon slightly (lattice parameter of the substrate less by from 0.1 to 10% than that of Si), and preferably a substrate with a lattice parameter less by from 0.5 to 5% than that of Si.

In the event that the group IVA element is an Si₁₋ₓGeₓ alloy, the same procedure is used for the choice of the substrate, i.e. the interstitial is stabilized with respect to the substitutional but without excess. To this end, a substrate is used with a lattice parameter smaller than that of the Si₁₋ₓGeₓ alloy if the interstitial is stable at equilibrium, and a substrate with a lattice parameter greater than that of the Si₁₋ₓGeₓ alloy if the substitutional is stable at equilibrium. A limit established theoretically at around x<0.25 (x≈0.16) is found in the literature for this change in stability (Da Silva Phys. Rev. B 70, 193205 (2004)).

When the group IVA element is an Si₁₋ₓGeₓ alloy with 0.25≦x≦1, it is necessary to expand by using a substrate with a lattice parameter greater by from 0.1 to 10% than that of Si₁₋ₓGeₓ in the method of the invention, so as to favor the interstitial position of the transition element and in order to obtain the material according to the invention.

When the group IVA element is an Si₁₋ₓGeₓ alloy with 0≦x≦0.16, it is necessary to contract by using a substrate with a lattice parameter less by from 0.1 to 10% than that of Si₁₋ₓGeₓ in the method of the invention in order to reduce the stability of the interstitial with respect to the substitutional and in order to obtain the material according to the invention.

The lattice parameter of a substitution alloy, such as those used as substrates in the present invention, can be calculated with the aid of methods known well to the person skilled in the art and described particularly to first approximation by Végard's law which indicates that, in the case of alloys in which there is miscibility throughout the concentration scale, the parameter of the unit cell of the alloy varies linearly between the respective parameters of the two pure compounds.

The lattice parameters of various semiconductor alloys may be found for example at: http://www.ioffe.rssi.ru/SVA/NSM/Semicond/ or at: http://www.semiconductors.co.uk/home.htm or in “Semiconductor Materials”, Lev I. Berger, (CRC Press, Boca Raton, 1997) or in “Fundamentals of Semiconductors”, Peter Y. Yu and Manuel Cardona, (Springer, 2005).

When the group IVA element is an Si₁₋ₓGeₓ alloy, as explained above, the choice is made either to compress or to expand as a function of the germanium concentration x.

A suitable substrate can be obtained easily in each case: in particular, it is possible to use a substrate of formula (whose lattice parameter varies from 5.43 to 5.66 Å with z increasing from 0 to 1) or a substrate of formula In_{1-y}Ga_{y}P (whose lattice parameter varies from 5.44 to 5.86 Å with y decreasing from 1 to 0).

According to a second variant, the method of manufacturing a magnetic material according to the invention includes at least one molecular beam epitaxy step comprising simultaneous deposition of at least one transition element selected from the group consisting of manganese, iron, cobalt, nickel, vanadium and chromium and at least one other element selected from group IVA of the periodic table onto a substrate whose lattice mismatch with the element(s) selected from group IVA of the periodic table is less than 1% in absolute value, preferably less than 0.5%, and whose temperature during the growth of the crystals is between 80° C. and 200° C., preferably between 100° C. and 150° C., leading to a thin film of said group IVA semiconductor being obtained, in which the atoms of magnetic element(s) are inserted.

This variant is used when the group IVA element is an alloy of formula Siᵢ₋ₓGeₓ with 0.16≦x≦0.25. The growth can then be carried out directly on an Si_{1-y}Ge_{y} substrate with x≈y, because the relative stability of the interstitials with respect to the substitutionals makes it possible to obtain the magnetic phase of the material of the present invention without strain. A slight positive or negative strain may nevertheless advantageously be applied in order to favor the correct ratio of substitutionals with respect to the interstitials, because it is this ratio which controls the Curie temperature and the total magnetization of the structure.

The positioning of the atoms of the transition element with respect to the semiconductor structure may be observed as a function of their concentration either by X-ray diffraction of the concentration is greater than 10% by volume, or by EXAFS (standing for Extended X-Ray Absorption Fine Structure) for all the concentrations (although this method requires a synchrotron) or more simply by the RBS technique (standing for Rutherford Backscattering Spectrometry) for all concentrations.

The RBS technique consists in examining the energy distribution of highly energetic (>2 MeV) He ions backscattered by the sample's region close to the surface. The composition and distribution in depth of the elements present in the sample can be deduced therefrom. Quantitative data about the crystallinity of the material can also be obtained.

More precisely, the so-called “channeling” technique can be used, an example of which is given in the following publication which measures the ratio of interstitials and substitutionals in a GeMn structure with nanocolumns: “Dopant segregation and giant magnetoresistance in manganese-doped germanium” A. P. Li et al., Phys. Rev. B 75, 201201 (2007).

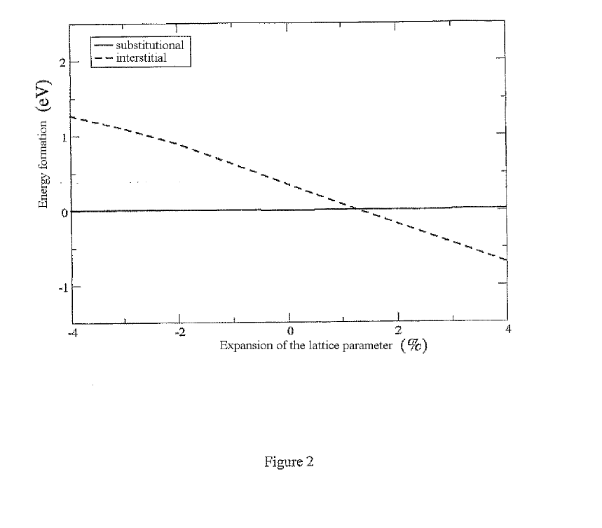

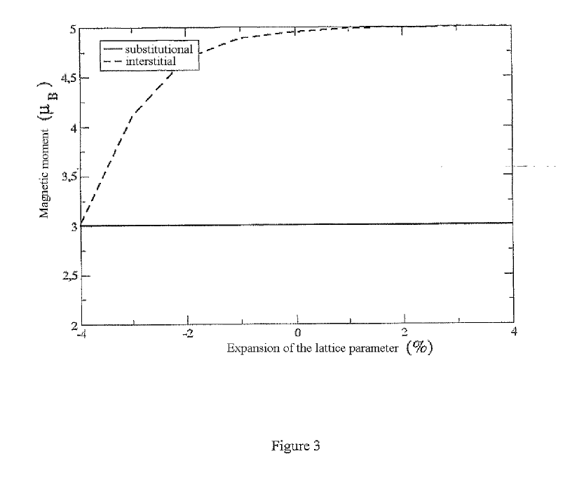

According to the prior art, it is assumed that in germanium it is the substitutional position which is more stable than the interstitial position (for example Da Silva Phys. Rev. B 70, 193205 (2004)). Furthermore, it is also assumed that in DMS it is necessary to favor this position of Ge substitution by Mn if the intention is to obtain a ferromagnetic compound (for example in GaMnAs: K. M. Yu et al., Phys. Rev. B 65, 201303 (2002); A. H. MacDonald Nat. Mat. 4 195 (2005)). Lastly, it is also assumed that in DMS the presence of interstitials decreases and limits the Curie temperature of the material (for example in GaMnN: K. M. Yu et al., Phys. Rev. B 65, 201303 (2002); A. H. MacDonald Nat. Mat. 4 195 (2005)). Thus, the method and the material of the invention go against the knowledge of the person skilled in the art about DMS since it has been shown that by maximizing the concentration of manganese at an interstitial position, a magnetic material is obtained at room temperature. The manganese is stabilized in this position by the stress imposed by the substrate. Furthermore, this method makes it possible to obtain a high value of the magnetization, as shown by the curve in FIG. 3: the moment of the interstitial is always greater than that of the substitutional; it increases to its saturation value during expansion of the lattice. In order to have a ferromagnetic coupling between these interstitial manganeses, on the other hand, it is necessary to have a small proportion of manganese in a substitutional position. In the structure obtained (FIG. 1-d), the interstitial manganeses are second neighbors with one another while the substitutionals are first neighbors of at least 2 interstitial manganeses, which leads to a substitutional ratio of about 20% with respect to the total Mn. This implies that the tension applied in order to stabilize such a structure is obtained in the germanium by virtue of an expansion strain which stabilizes the interstitial with respect to the substitutional (FIG. 2). This strain is obtained by virtue of the use of a substrate having a lattice mismatch, as described above. Nevertheless, this strain should not be too great so as also to allow the existence of a few manganese atoms in a substitutional position, as described above. This latter point explains why in silicon, for which the interstitial position is stable without strain, it is necessary to carry out the growth on a substrate which compresses the silicon in order to reduce the stability of the interstitial with respect to the substitutional.

The use of a compressive strain in order to stabilize diluted magnetic semiconductors in silicon has recently been proposed by Z. Z. Zhang, et al. (“First-principles study of transition metal impurities in Si” Phys. Rev. B 77, 155201 (2008)). In this work on electronic structure calculation, however, the aim of the strain is to stabilize manganese in a substitutional position and not in an interstitial position, as in the present invention. These data can be used to select the optimal lattice mismatch between the substrate and the silicon when the latter is employed as a group IVA element: ≦4% for V, ≦−4% for Cr, <−2% for Mn, <−3% for Fe, <−−3% for Co and <−3% for Ni.

The key parameters in the method of the invention are:
the choice of the substrate (expansion or contraction of the substrate with respect to the group IVA element in the case of the first variant, or on the other hand the choice of a substrate with a lattice parameter substantially identical to the group IVA element in the case of the second variant),
the flow rate of the group IVA element, advantageously germanium, and the flow rate of the transition element, advantageously manganese, during the deposition (concentration),
the thickness of the deposited layer (as well as the optional Ge buffer layer), which is selected so as to avoid relaxation of the deposit,
the temperature of the substrate during the deposition.

The maximum deposition thickness in order to avoid relaxation of the magnetic material deposit depends on the composition of this material (choice of the atoms and their proportions), its concentration and the expansion of the support. It can be determined with the aid of methods known well to the person skilled in the art, such as the Matthews-Blakeslee method, a description of which is given for example in F. Tinjod Doctoral Thesis UJF Grenoble 2003.

Advantageously, the atomic fraction of the magnetic element(s) in the material is preferably between 15% and 60% with respect to the entire material, and advantageously it is between 20 and 45%; it results from the relative concentration of the magnetic elements and the group IVA elements during the deposition: the elements are deposited by using an average ratio [deposition rate of the magnetic element(s)/deposition rate of all the elements which is between 15% and 60%, advantageously between 20 and 45%.

Preferably, the at least one magnetic element(s) is manganese, chromium or vanadium, and advantageously manganese.

Also preferably, the other group IVA element(s) deposited simultaneously are germanium, silicon or one of their alloys.

Even more preferably, the transition element and the group IVA element which are deposited simultaneously are respectively manganese and germanium and/or silicon, in order to obtain a GeMn, SiMn or SiGeMn magnetic material, or alternatively as a variant of the GeMnX, SiMnX or SiGeMnX type where X is a metal or an alloy of a metal which may be selected for example from among iron, cobalt, nickel, vanadium or chromium, preferably from between chromium and vanadium.

In the case in which Ge is selected as the semiconductor element and Mn as the transition element, with the set of suitable parameters a homogeneous layer of GeMn is obtained which is magnetic above room temperature with a manganese concentration that can range from 15 to 60%, advantageously from 20 to 45%. The GeMn thickness is advantageously between 0.1 nm and 1 μm, preferably between 0.3 nm and 1 μm.

Advantageously, the method according to the invention furthermore comprises deposition of a germanium “buffer” layer on the substrate, prior to the simultaneous deposition of germanium and manganese in order to obtain the thin film, so as to obtain a surface which is as smooth as possible on the atomic scale for bidimensional growth of the germanium-manganese film. In the case in which the group IVA element is Si or an alloy of Ge and Si, the buffer layer respectively consists of Si or the same Ge/Si alloy.

The thickness of the buffer layer, when such a layer is present, is also calculated so as to avoid relaxation of the semiconductor. The person skilled in the art may use the Matthews-Blakeslee method, a description of which is given for example in F. Tinjod Doctoral Thesis UJF Grenoble 2003, in order to calculate this maximum thickness.

In more detail, in the case in which the transition element is manganese and the semiconductor is germanium, the synthesis of the magnetic material is carried out as in the case of the method of WO2007/090946 by low-temperature molecular beam epitaxy (MBE). In this embodiment in an ultra-vacuum, the germanium and the manganese are evaporated from solid sources onto a substrate.

The main difference from the prior art method comes from the choice of the substrate on which the MBE growth is carried out. In the method of the invention, the crystal lattice mismatch between the germanium and the substrate is of essential importance.

The substrate is thus selected so as to have a lattice parameter which is a few percent greater than that of germanium. A substrate or support may be selected which has a lattice parameter mismatch with respect to germanium of between 1 and 7%, advantageously between 2 and 4%. For example, the compound (Ga₁₋ₓInₓ)As may be used as a substrate, the indium concentration fixing the mismatch of the lattice parameters: from approximately −0.1% for x=0 to approximately +7% for x=1.

For a (Ga₁₋ₓInₓ)As substrate, the mismatch (D) is given as an estimate by the formula:

D=40x/5.66.

The growth procedure is carried out according to a standard method known well to the person skilled in the art:
a) deoxidation of the substrate or desorption of the protective layer in order to obtain a surface which is “clean” enough to make it possible to carry out 2D epitaxy according to the rules of the person skilled in the art (chemical cleaning, plasma treatment).
b) application of a method making it possible, if necessary, to smooth the surface to be epitaxially grown on and/or make a diffusion barrier. For example, a germanium buffer layer may be deposited in epitaxy with the substrate, with a thickness thin enough to avoid its relaxation, for example a thickness of between 0.1 nm and 100 nm. This critical thickness depends on the lattice mismatch according to the rules known well to the person skilled in the art.
c) deposition of a GeMn layer on the Ge buffer layer stressed by the substrate, or directly on the substrate when there is no buffer layer. The thickness of the layer is also controlled so as to remain below the critical relaxation thickness, and in particular it is between 0.1 nm and 1 μm. This thickness also depends on the initial lattice mismatch. The GeMn is deposited at a low temperature (<200° C.) with germanium and manganese partial pressures in the flow rate level with the substrate of between 0.8·10⁻⁸ and 8·10⁻⁸ Torr and between 0.1·10⁻⁹ and 100·10⁻⁹ Torr. Thus, the deposition rate is of the order of from 0.01 to 0.1 nm/s. The relative concentration of manganese is between 15 and 60%, advantageously between 20 and 45%, as a function of the respective ratio of the two partial pressures used.

Under these growth conditions, the deposit is obtained in the form of a thin film in which the manganese is distributed substantially homogeneously. The manganese occupies in particular interstitial positions of the diamond lattice of the germanium. This stabilization is favored by the stress applied by the substrate during the growth of the layer. This material has a Curie temperature above 350 K. Neither its composition nor its structure resembles the known compounds of the GeMn phase diagram.

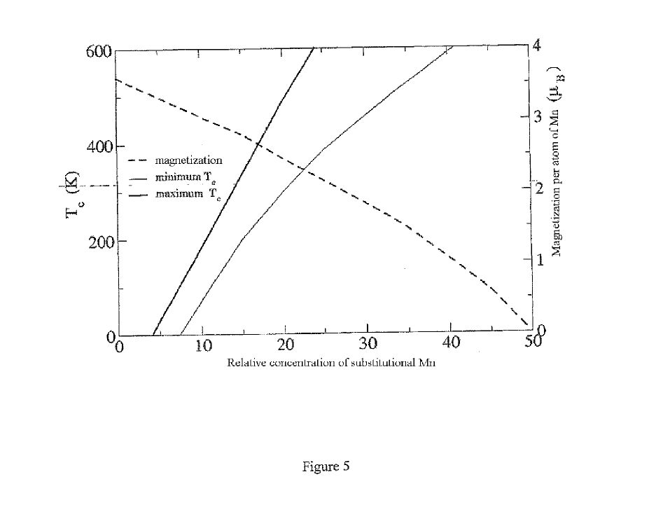

These modulations of the parameters of the method quite clearly have the effect of modifying both the thickness of the GeMn layer which can be envisaged without relaxation, the magnetization of the material in the neutral state and its Curie temperature, while achieving the production of GeMn layers which are magnetic above room temperature. By way of example, FIG. 5 presents the change in the Curie temperature and the magnetization in the neutral state (expressed in terms of the manganese concentration) as a function of the relative substitutional concentration with respect to the total number of manganese atoms in the germanium. The growth parameters can therefore be adjusted as a function of the applications, in order to find a compromise between a high Curie temperature and a strong magnetization in the neutral state. The working point is determined on the basis of the total concentration of manganese as well as the ratio of substitutional/interstitial Mn, which may be measured for example by RBS.

The invention is based on the stabilization of manganese in an interstitial position of the diamond lattice of germanium. The expansion factor for stabilizing this interstitial position with respect to the substitutional position is defined using results of calculations based on the electronic structure of the solids, which are presented in FIG. 2. A stability reversal can be seen starting from an expansion of about 1%. A margin of 1-2% is preferably applied in order to ensure this stabilization in the specimens fabricated. Furthermore, the factor may expediently be adjusted in order to obtain a compromise between the stability of these interstitials and the critical relaxation thickness of the Ge buffer and GeMn layers.

In more detail, the material of the invention is in the form of a film consisting of a homogeneous crystalline alloy of an element selected from group IVA of the periodic table, advantageously germanium, and a transition element, advantageously manganese. It has a Curie temperature (Tc) greater than or equal to 350 K. These very high Curie temperature values, which can be measured using a magnetometer of the “SQUID” type (i.e. “Superconducting Quantum Interference Device”) have never previously been achieved for films of homogeneous composition of group IVA semiconductors mixed with magnetic elements.

The magnetic material of the invention also exhibits an extraordinary Hall effect (abbreviated to “EHE”) at a temperature above 300 K, which may reach at least 350 K.

These very high values of temperatures at which this “EHE” effect occurs, the temperatures being measured using a magneto-transport arrangement equipped with a cryostat and a supraconducting coil, have never previously been achieved for films of homogeneous composition of group IVA semiconductors mixed with magnetic elements.

In comparison with the materials described in WO2007/090946, the material of the invention is distinguished by its homogeneous nature. This characteristic can be observed in several ways: if two samples are taken at random from the material and the concentration of the transition element is evaluated, it lies in a value interval of ±5% around an average value. A study of the material by X-ray diffraction also shows that the atomic structure of the material is substantially homogeneous. Lastly, the physical properties of the material (magnetization, conductivity, lattice parameter) are substantially identical at every point on the surface of the material film: this homogeneity makes it possible to inject spins at any point on the surface of the material, which is not possible with the material described in WO2007/090946.

The homogeneity of the material in fact has the advantage that the spin injection surface is larger. This spin injection function and its associated surface are important for applications such as a spin FET transistor or a spin Qbit. Likewise, if the material is used as a magnetic layer in an information storage device of the MRAM type or in a spin valve, the possibility of using it in the form of a homogeneous film is necessary, particularly during a lithography step if there is one. The benefit of such a material then resides in its ability to be epitaxially grown easily on semiconductors (Si, Ge, . . . diamond lattice) without introducing extended defects. It also has the benefit that it can be localized by means of the stress transmitted by the substrate (in particular “bond/tilt” methods) for example for the co-integration of magnetic functions (magnetic sensors, magnetic memories, etc.) in conventional microelectronics.

The material of the invention can be used for a variety of applications, either as a source of a current of spin-polarized carriers in silicon or germanium, or as a magnetic element in devices of the spin valve or magnetic tunnel junction type, or conventionally as an (easily localizable) magnetized region which has a source of a magnetic field for applications in high-density magnetic recording. Devices using DMS and for which the materials of the invention could advantageously replace the DMS, are described in: Vutic et al., Reviews of Modern Physics, Volume 76, 323, April 2004.

The invention also relates to a wafer comprising a support as described above and at least one layer of a magnetic material of the invention. It optionally comprises an intermediate buffer layer as described above. This wafer is obtained by carrying out the method of the invention, and can be used in an electromagnetic device for the applications described above.

In the case in which this wafer is obtained by applying the method of the invention to a support having a lattice parameter mismatch with the group IVA element, distinction may be made between two different configurations:

According to a first variant of this aspect of the invention, this support has a strain, or lattice parameter mismatch with respect to the group IVA element, which is constant. This results in homogeneous deposition over the entire surface of this support.

According to a second variant, this support has a lattice parameter mismatch with respect to the group IVA element which varies as a function of a predetermined scheme. Thus, the film is grown on a substrate having one or more zones in which the strain (lattice parameter mismatch with respect to the semiconductor) is homogeneous and others in which the strain is distributed inhomogeneously. This makes it possible to grow zones of homogeneous magnetic film on a substrate according to a predetermined scheme. In contrast to the devices described in WO2007/090946, the dimensions and the distribution of the magnetic film zones in the deposit are then controlled and not random.

According to this variant, if Rs denotes the surface area ratio of the zones in which a strain is applied and the total surface area of the substrate, the total concentration of manganese may range from 15%×Rs to 60%×Rs, and preferably between 20%×Rs and 45%×Rs. During the growth by MBE, the manganese is preferentially concentrated at the zones level with the zones strained according to the selected scheme. The characteristics of the deposit in these zones are the same as those described for the deposit on a uniform substrate. In particular, the total concentration of manganese in these zones is then preferably between 20 and 45% with a substitutional ratio of preferably between 20 and 35%.

One well-known way of obtaining such a substrate is to use “bond/tilt” substrates, which make a dislocation network therefrom allowing localization of the quantum boxes whose growth is itself also sensitive to the deformation. This method is explained, for example, by A. Bourret. Surf. Sci. 432, p. 37, (1999).

Other strain localization methods are also possible: implantation, etching etc. In particular, reference may be made to M. Hanbückenet al., “Les nanosciences: Nanotechnologies et nanophysique” [The nanosciences: nanotechnologies and nanophysics], p. 50, Edition Belin by M. Lahmani, C. Dupas and P. Houdy (2004).

This variant may be highly beneficial for the co-integration of magnetic functions (magnetic sensors, magnetic memories, etc.) in conventional microelectronics or for the production of wafers with zones of different Tc according to a predetermined scheme.

An electronic component according to the invention may advantageously be of the diode type for injecting or collecting spins into or from another semiconductor, respectively, or such as an element sensitive to a magnetic field, and this component advantageously comprises a magnetic material according to the invention as defined above.

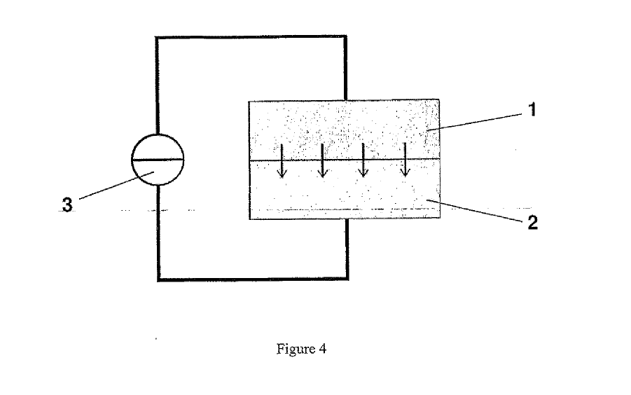

According to a first embodiment of the invention, it is a component of the diode type for injecting spins into or collecting spins from another semiconductor, for example of group IVA, as illustrated in FIG. 4, and comprising:
a first thin film (1) formed by a wafer having a magnetic material according to the invention deposited on a substrate,
a second thin film (2) formed by a semiconductor based on elements of groups IV, III-V or II-VI, or one of their alloys, in contact with which said first thin film is applied. If the first layer is p-doped, production of an Esaki diode by adding a heavily n-doped layer between the first and second layers makes it possible to convert the polarized holes into polarized electrons (the depolarization length of which is greater),
a source of a current of carriers (3) which is coupled to the first layer in order, in a first case, to selectively extract a spin-polarized current therefrom and inject it into the second layer or, in a second case, in order to selectively extract a current of spin-polarized carriers from the second layer and inject it into the first layer, so that the magnetic phase according to the invention of the first semiconductor emits or receives this spin-polarized current to or from the second semiconductor, respectively, depending on the first or second case. The fact that the material is not a semiconductor but simply a poor conductor is sufficient to avoid depolarization. (A. Fert and H. Jaffres, Physical Review B 64, 184420).

According to a second embodiment of the invention, the component is sensitive to a magnetic field and may be a magnetic field sensor, which comprises a thin film formed by a magnetic material according to the invention as defined above, for detecting or measuring said field by measuring a magnetoresistance effect in relation to a magnetic field applied perpendicularly to the thin film or in its plane.

It will be noted that this component makes it possible to overcome the “super-paramagnetism” phenomenon which characterizes diluted systems based on nanoparticules, and that the magnetoresistance measure according to the invention remains high even at room temperature in contrast to these diluted systems, which gives this component according to the invention excellent magnetic field measurement capacities.

A first use according to the invention of a magnetic material as described above consists in injecting or collecting a current of spin-polarized carriers by contact into or from another semiconductor based on Si, Ge, . . . (groups IV, III-V, II-VI) or an alloy thereof, at a temperature which is equal to or above 350 K, and may be equal to or above 400 K.

A second use according to the invention of a magnetic material as described above consists in measuring a magnetic field by measuring a magnetoresistance effect in said semiconductor, at a temperature which is equal to or above 350 K, and may be equal to or above 400 K.

It will be noted that the magnetic material according to the invention can equally well be used as a magnetic element in devices of the spin valve type, or as a magnetized region which has a source of a magnetic field for applications in high-density magnetic recording.

The magnetic material of the invention may also be used for the manufacture of a flat magnetic memory of the MRAM type (the stack of magnetic layers is not vertical, as in a conventional MRAM, but instead they are arranged beside one another on a conduction channel based on silicon, for example) particularly in the case in which it has zones with different Tc.

FIG. 1: magnetic element Mn in the crystalline structure of germanium (a), in a substitutional position (b) and interstitial position (c) and arrangement of the phase according to the structure of the material of the invention (d).

FIG. 2: change in the energy of formation of the two elementary point defects of manganese in germanium (substitutional site, tetrahedral interstitial site) as a function of the expansion in relation to the equilibrium lattice parameter of germanium.

FIG. 3: change in the magnetic moment carried by the manganese as a function of the expansion in relation to the equilibrium lattice parameter of germanium.

FIG. 4: schematic representation of a component of the diode type for injecting spins into another semiconductor.

FIG. 5: change in the Curie temperature evaluated from the interchange integral as a function of the relative concentration of substitutional Mn in GeMn for an interstitial manganese concentration fixed at one third of the total number of atoms.

1. A magnetic material, characterized in that it is in the form of a film consisting of a homogeneous crystalline alloy of an element selected from group IVA of the periodic table and a transition element selected from the group consisting of manganese, iron, cobalt, nickel, vanadium and chromium, the atomic fraction of the magnetic element(s) being between 20 and 45% with respect to the entire material.

2. The material as claimed in claim 1, wherein the transition element is manganese and the element selected from group IVA is germanium.

3. The material as claimed in claim 2, wherein the GeMn thickness is between 0.1 nm and 1 μm.

4. The material as claimed in claim 1, which is deposited on a substrate selected from among the compounds of formula:
In₁₋ₓGaₓAs, GaAs₁₋ₓSbₓ, In₁₋ₓGaₓP, Si₁₋ₓGeₓ
where x represents a number such that
0≦x≦1 or
Si_{1-x-y}GeₓC_{y}
where x and y represent numbers such that
0≦x, 0≦y, 0≦x+y≦1.

5. The material as claimed in claim 1, which has a Curie temperature (Tc) greater than or equal to 350 K.

6. The material as claimed in claim 1, which exhibits an extraordinary Hall effect at a temperature above 300 K.

7. The material as claimed in claim 1, wherein between 15 and 45% of the transition element is in a substitutional position with respect to the total quantity of transition element.

8. An electronic component comprising at least one layer of a material as claimed in claim 1.

9. The component as claimed in claim 8 of the diode type for injecting spins into or collecting spins from another semiconductor.

10. The component as claimed in claim 8 of the magnetic field sensor type.

11. A method of manufacturing a magnetic material as claimed in claim 1, including at least one molecular beam epitaxy step comprising simultaneous deposition of at least one transition element selected from the group consisting of manganese, iron, cobalt, nickel, vanadium and chromium and at least one other element selected from group IVA of the periodic table onto a substrate whose lattice mismatch with the element(s) selected from group IVA of the periodic table is between 0.1 and 10% in absolute value, and whose temperature during the growth of the crystals is between 80° C. and 200° C.

12. The method as claimed in claim 11, wherein the group IVA element of the periodic table is selected from among Ge, Si and their alloys of formula Si₁₋ₓGeₓ with 0≦x≦0.16 and 0.25≦x≦1.

13. The method as claimed in claim 11, wherein the group IVA element is Ge and the transition element is Mn, the lattice parameter mismatch of Ge with the support being between 2 and 4%.

14. The method as claimed in claim 13 which comprises the steps:
(a) deoxidation of the substrate or desorption of the protective layer;
(b) deposition of a Ge buffer layer with a thickness of between 0.1 nm and 100 nm;
(c) deposition of a GeMn layer, the thickness of the layer being between 0.1 nm and 1 μm, the GeMn deposition being carried out at a temperature <200° C. with germanium and manganese partial pressures in the flow rate level with the substrate of between 0.8·10⁻⁸ and 8·10⁻⁸ Torr for Ge and between 0.1·10⁻⁹ and 100·10⁻⁹ Torr for Mn, and a relative concentration of manganese between 15 and 60%.

15. A method of manufacturing a magnetic material as claimed in claim 1, including at least one molecular beam epitaxy step comprising simultaneous deposition of at least one transition element selected from the group consisting of manganese, iron, cobalt, nickel, vanadium and chromium and at least one other element selected from group IVA of the periodic table, which is an alloy of formula Si₁₋ₓGeₓ with 0.16≦x≦0.25, onto a substrate whose lattice mismatch with the element(s) selected from group IVA of the periodic table is less than 1% in absolute value, preferably less than 0.5%, and whose temperature during the growth of the crystals is between 80° C. and 200° C., preferably between 100° C. and 150° C.

16. The method as claimed in claim 11, wherein the substrate consists of a binary or ternary or optionally quaternary semiconductor alloy of diamond or zinc blende structure.

17. The method as claimed in claim 16, wherein the atoms involved in the composition of the substrate are selected from among the following elements:
Al, In, Ga, As, Sb, N, P, C, Si, Ge.

18. The method as claimed in claim 11, wherein the elements are deposited by using an average ratio [deposition rate of the magnetic element(s)/deposition rate of all the elements] which is between 20 and 45%.

19. A wafer comprising a substrate and at least one layer of a material as claimed in claim 1.

20. The wafer as claimed in claim 19, wherein the substrate has a lattice parameter mismatch with respect to the group IVA element, and this mismatch is constant over the entire surface.

21. The wafer as claimed in claim 19, wherein the substrate has a lattice parameter mismatch with respect to the group IVA element which varies according to a predetermined scheme.

22-23. (canceled)
